(19) United States
(12) Patent Application Publication
(10) Pub. No.: US 2026/0101786 A1
(43) Pub. Date: Apr. 9, 2026

(54) SEMICONDUCTOR PACKAGE INCLUDING CONDUCTIVE POST

(71) Applicant: SAMSUNG ELECTRONICS CO., LTD., Suwon-si (KR)

(72) Inventors: Seonghoon BAE, Suwon-si (KR); Sanghyuck OH, Suwon-si (KR); Kwangok JEONG, Suwon-si (KR); Jeonggi JIN, Suwon-si (KR); Wonho CHOI, Suwon-si (KR); Juil CHOI, Suwon-si (KR)

(73) Assignee: SAMSUNG ELECTRONICS CO., LTD., Suwon-si (KR)

(21) Appl. No.: 19/280,452

(22) Filed: Jul. 25, 2025

(30) Foreign Application Priority Data
Oct. 14, 2024 (KR) 10-2024-0139158

(51) Int. Cl. H01L 23/498; H01L 23/00; H01L 23/538; H01L 25/18; H10B 80/00; H10D 80/30

(52) U.S. Cl. CPC H10W 70/65; H10W 70/611; H10W 90/401; H10B 80/00; H10D 80/30; H10W 74/15; H10W 90/00; H10W 90/724; H10W 90/734; H10W 90/752; H10W 90/754

(57) ABSTRACT

A semiconductor package includes a lower redistribution structure including a lower redistribution layer, and a connection structure disposed on the lower redistribution structure. The connection structure includes a lower chip structure electrically connected to the lower redistribution layer, conductive posts disposed around the lower chip structure, and an encapsulant covering the lower chip structure and the conductive posts. In a plan view, the connection structure includes a plurality of regions arranged in a first horizontal direction. The plurality of regions are spaced apart from the lower chip structure in a second horizontal direction, intersecting the first horizontal direction. The plurality of regions include a first region and a second region, farther from a center of the lower chip structure than the first region. The conductive posts in the second region have a shape, different from that of the conductive posts in the first region.

### CROSS-REFERENCE TO RELATED APPLICATION(S)

This application claims benefit of priority to Korean Patent Application No. 10-2024-0139158 filed on Oct. 14, 2024 in the Korean Intellectual Property Office, the disclosure of which is incorporated herein by reference in its entirety.

### BACKGROUND

The present inventive concept relates to a semiconductor package including a conductive post.

As demand for implementation of high performance, high speed, and/or multifunctionalization of semiconductor devices increases, a degree of integration of semiconductor devices has been increasing. In manufacturing semiconductor devices having a fine pattern corresponding to the trend for a high degree of integration of semiconductor devices, it is necessary to implement patterns having a fine width or a fine separation distance.

### SUMMARY

An aspect of the present inventive concept provides conductive posts disposed around a lower chip structure.

According to an aspect of the present inventive concept, there is provided a semiconductor package including a lower redistribution structure including a lower redistribution layer, and a connection structure disposed on the lower redistribution structure. The connection structure may include a lower chip structure electrically connected to the lower redistribution layer, conductive posts disposed around the lower chip structure, and an encapsulant covering the lower chip structure and the conductive posts. In a plan view, the connection structure may include a plurality of regions arranged in a first horizontal direction. The plurality of regions may be spaced apart from the lower chip structure in a second horizontal direction, intersecting the first horizontal direction. The plurality of regions may include a first region and a second region, farther from a center of the lower chip structure than the first region. The conductive posts in the second region may have a shape, different from that of the conductive posts in the first region.

According to another aspect of the present inventive concept, there is provided a semiconductor package including a lower redistribution structure including a lower redistribution layer, a lower chip structure disposed on the lower redistribution structure, the lower chip structure electrically connected to the lower redistribution layer, conductive posts arranged on the lower redistribution structure in a first horizontal direction, the conductive posts spaced apart from the lower chip structure in a second horizontal direction, intersecting the first horizontal direction, and an encapsulant covering the lower chip structure and the conductive posts. In a plan view, a pattern density of the conductive posts may decrease as a distance from a center of the lower chip structure increases. The conductive posts may include a first conductive post and a second conductive post farther from the center of the lower chip structure than the first conductive post. A cross-sectional area of the first conductive post may be greater than a cross-sectional area of the second conductive post, and the first conductive post may have a shape, different from that of the second conductive post.

According to another aspect of the present inventive concept, there is provided a semiconductor package including a lower redistribution structure including a lower redistribution layer, a bump structure disposed below the lower redistribution structure, the bump structure electrically connected to the lower redistribution layer, and a connection structure disposed on the lower redistribution structure. The connection structure may include a lower chip structure electrically connected to the lower redistribution layer, conductive posts disposed around the lower chip structure, and an encapsulant covering the lower chip structure and the conductive posts. Upper surfaces of the conductive posts may be coplanar with the encapsulant. In a plan view, the connection structure may include a plurality of regions arranged in a first horizontal direction. The plurality of regions may be spaced apart from the lower chip structure in a second horizontal direction, intersecting the first horizontal direction. The plurality of regions may include a first region and a second region, farther from a center of the lower chip structure than the first region. A pattern density of the conductive posts in the second region may be lower than a pattern density of the conductive posts in the first region. The conductive posts in the second region may have a circular shape, and the conductive posts in the first region may have a rectangular shape.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view of a semiconductor package according to an example embodiment;

FIG. 2 is a vertical cross-sectional view of the semiconductor package illustrated in FIG. 1, taken along line I-I′;

FIG. 3 is a vertical cross-sectional view of the semiconductor package illustrated in FIG. 1, taken along line II-II′;

FIG. 4 is a partially enlarged view of the semiconductor package illustrated in FIG. 1;

FIG. 5 is a partially enlarged view of the semiconductor package illustrated in FIG. 1;

FIGS. 6 and 7 are vertical cross-sectional views of a semiconductor package according to an example embodiment;

FIGS. 8 and 9 are plan views of a semiconductor package according to an example embodiment;

FIG. 10 is a plan view of a semiconductor package according to an example embodiment;

FIG. 11 illustrates conductive posts according to an example embodiment;

FIG. 12 is a vertical cross-sectional view of a semiconductor package according to an example embodiment; and

FIGS. 13A to 13H are plan views and vertical cross-sectional views of a method of manufacturing a semiconductor package according to an example embodiment.

### DETAILED DESCRIPTION

Hereinafter, preferred example embodiments of the present inventive concept will be described with reference to the accompanying drawings as follows.

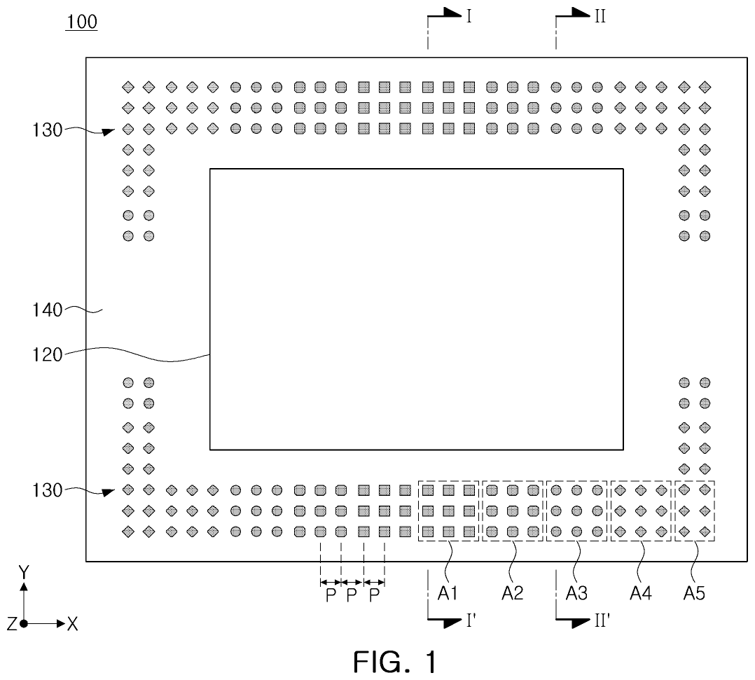

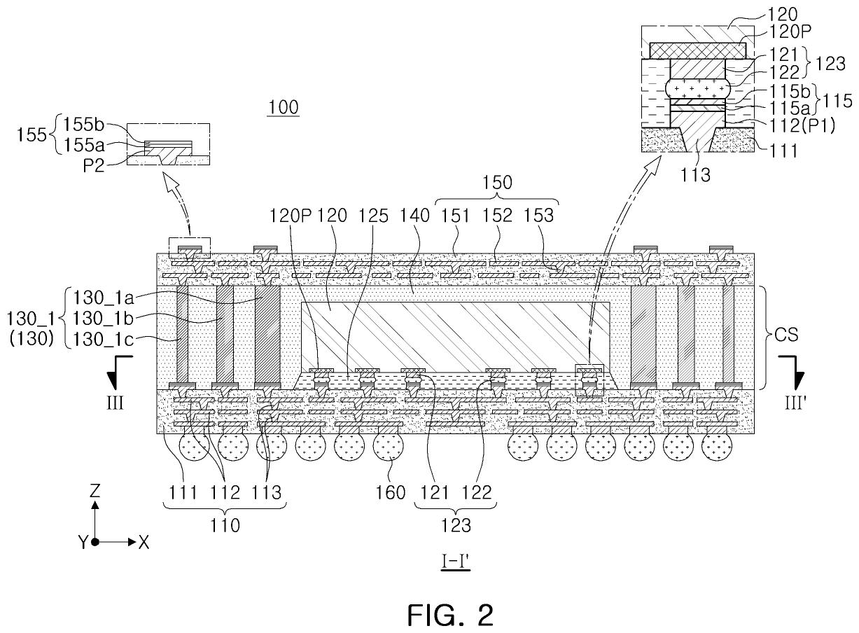

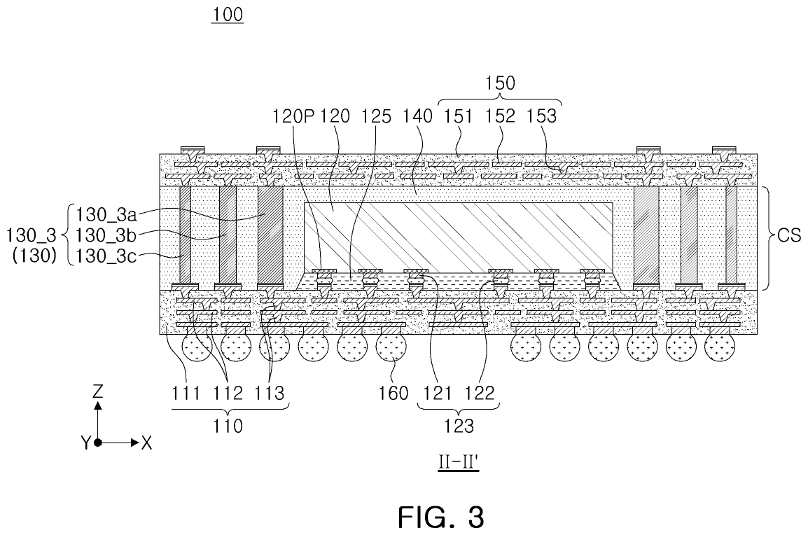

FIG. 1 is a plan view of a semiconductor package according to an example embodiment. FIG. 2 is a vertical cross-sectional view of the semiconductor package illustrated in FIG. 1, taken along line I-I′. FIG. 3 is a vertical cross-sectional view of the semiconductor package illustrated in FIG. 1, taken along line II-II′. FIG. 1 may correspond to a cross-sectional view of the semiconductor package illustrated in FIG. 2, taken along line III-III′.

Referring to FIGS. 1 to 3, a semiconductor package 100 according to an example embodiment of the present disclosure may include a lower redistribution structure 110, a lower chip structure 120, a conductive post 130, an encapsulant 140, an upper redistribution structure 150, and a bump structure 160.

The lower redistribution structure 110 may be a support substrate on which the chip structure 120 is mounted, and may include a lower insulating layer 111, a lower redistribution layer 112, and a lower redistribution via 113.

The lower insulating layer 111 may include an insulating resin. The insulating resin may include a thermosetting resin such as an epoxy resin, a thermoplastic resin such as polyimide, or a resin, for example, a prepreg, an Ajinomoto build-up film (ABF), FR-4, or BT, in which the thermosetting resin or the thermoplastic resin is impregnated with an inorganic filler. For example, the lower insulating layer 111 may include a photosensitive resin such as a photoimageable dielectric (PID). The lower insulating layer 111 may include a plurality of lower insulating layers 111 stacked in a vertical direction (Z-axis direction). Depending on a process thereof, the plurality of insulating layers 111 may have unclear boundaries therebetween.

The lower redistribution layer 112 may be disposed on or in the lower insulating layer 111, and may redistribute a connection pad 120P of the chip structure 120. The lower redistribution layer 112 may include, for example, a metal material including copper (Cu), aluminum (Al), silver (Ag), tin (Sn), gold (Au), nickel (Ni), lead (Pb), titanium (Ti), or alloys thereof. The lower redistribution layer 112 may perform various functions according to a design thereof. For example, the lower redistribution layer 112 may include a ground (GND) pattern, a power (PWR) pattern, and a signal(S) pattern. Here, the signal(S) pattern may be defined as a transmission path of various signals, for example, data signals or the like, excluding the ground (GND) pattern, the power (PWR) pattern, or the like.

The number of redistribution layers, included in the lower redistribution layers 112, may be greater than or less than the number of those illustrated in the drawings. For example, the lower redistribution layer 112 may include a first pad portion P1 disposed on an upper surface of the lower redistribution structure 110. The first pad portion P1 may be connected to the connection pad 120P of the chip structure 120 and the conductive post 130. For example, A barrier layer 115 may be disposed on a surface of the first pad portion P1. The barrier layer 115 may include an oxidation-resistant material, for example, nickel (Ni), gold (Au), or alloys thereof. For example, the barrier layer 115 may include a lower layer 115a including nickel (Ni) and an upper layer 115b including gold (Au).

The lower redistribution via 113 may pass through the lower insulating layer 111, and may be electrically connected to the lower redistribution layer 112. For example, the lower redistribution via 113 may interconnect the lower redistribution layers 112 having different levels. The lower redistribution via 113 may include a signal via, a ground via, and a power via. The lower redistribution via 113 may include, for example, a metal material including copper (Cu), aluminum (Al), silver (Ag), tin (Sn), gold (Au), nickel (Ni), lead (Pb), titanium (Ti), or alloy thereof. The lower redistribution via 113 may be a filled via in which a metal material is filled in a via hole or a conformal via in which a metal material extends along an inner wall of a via hole.

The chip structure 120 may include the connection pad 120P disposed the an upper surface of the lower redistribution structure 110, the connection pad 120P electrically connected to the lower redistribution layer 112. The chip structure 120 may be an integrated circuit (IC) in a bare state in which no bump or interconnection layer is formed, but the present inventive concept is not limited thereto, and may also be a packaged-type integrated circuit. The integrated circuit may be a processor chip such as a central processing unit (CPU), a graphics processing unit (GPU), a field programmable gate array (FPGA), an application processor (AP), a digital signal processor, an encryption processor, a microprocessor, a microcontroller, or the like, but the present inventive concept is not limited thereto, and may be a logic chip such as an analog-to-digital converter or an application-specific IC (ASIC), and may be a memory chip including a volatile memory such as a dynamic RAM (DRAM) or a static RAM (SRAM), and a nonvolatile memory such as a phase change RAM (PRAM), a magnetic RAM (MRAM), a dynamic RAM (RRAM), or a flash memory.

In an example embodiment, the chip structure 120 may be formed of a single semiconductor chip, but the present inventive concept is not limited thereto. In some example embodiments, the chip structure 120 may be formed by stacking a plurality of semiconductor chips.

The chip structure 120 may include a connection bump 123 connecting the connection pad 120P to the first pad portion P1 of the lower redistribution layer 112. The connection bump 123 may be disposed between the first pad portion P1 and the connection pad 120P. For example, the connection bump 123 may include a pillar portion in contact with the connection pad 120P, and a solder portion 122 in contact with the barrier layer 115. In some example embodiments, an underfill layer 125 may be disposed between the chip structure 120 and the lower redistribution structure 110. The underfill layer 125 may include an insulating resin such as an epoxy resin, and may physically and electrically protect the connection bumps 123. The underfill layer 125 may have a capillary underfill (CUF) structure, but the present inventive concept is not limited thereto. In some example embodiments, the underfill layer 125 may have a mole underfill (MUF) structure integrated with the encapsulant 140.

The conductive post 130 may pass through the encapsulant 140 between the lower redistribution structure 110 and the upper redistribution structure 150, and may electrically connect the lower redistribution layer 112 and the upper redistribution layer 152 to each other. The conductive posts 130 may be disposed to have a predetermined pitch P. Here, the pitch P may refer to a horizontal distance between centers of the conductive posts 130. The conductive post 130 may extend in a direction (Z-direction), perpendicular to the upper surface of the lower redistribution structure 110 in the encapsulant 140. An upper surface of the conductive post 130 may be exposed from the encapsulant 140, and may be coplanar with an upper surface of the encapsulant 140. For example, the conductive post 130 may have a columnar shape, passing through the encapsulant 140. However, the shape of the conductive post 130 is not limited thereto. In FIG. 1, the lower chip structure 120 may be disposed at a center of the lower redistribution structure 110, and the conductive posts 130 may be disposed to surround the lower chip structure 120, but the present inventive concept is not limited thereto. In some example embodiments, the lower chip structure 120 may be disposed at an edge of the lower redistribution structure 110.

The conductive post 130 may include a metal material such as copper (Cu). In some example embodiments, a metal seed layer (not illustrated) including titanium (Ti) or copper (Cu), may be formed on a lower surface of the conductive post 130.

The encapsulant 140 may fill a space between the lower redistribution structure 110 and the upper redistribution structure 150, and encapsulate at least a portion of each of the chip structure 120 and the conductive post 130. The encapsulant 140 may be a resin including epoxy or polyimide. For example, the resin may include a bisphenol-based epoxy resin, a polycyclic aromatic epoxy resin, an o-cresol novolac epoxy resin, a biphenyl-group epoxy resin, or a naphthalene-based epoxy resin. For example, the encapsulant 140 may include an EMC.

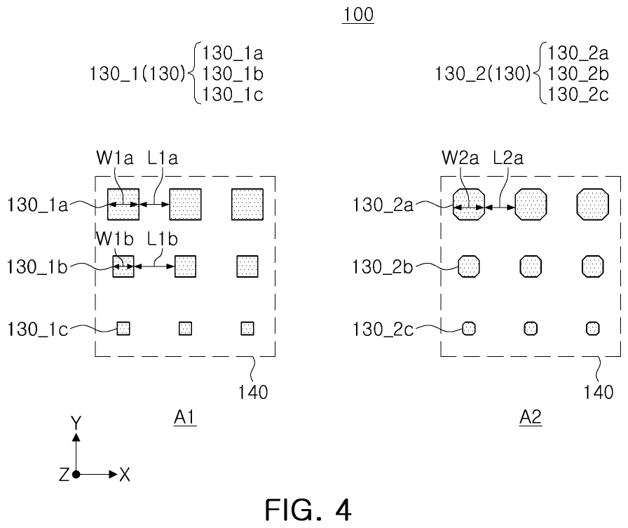

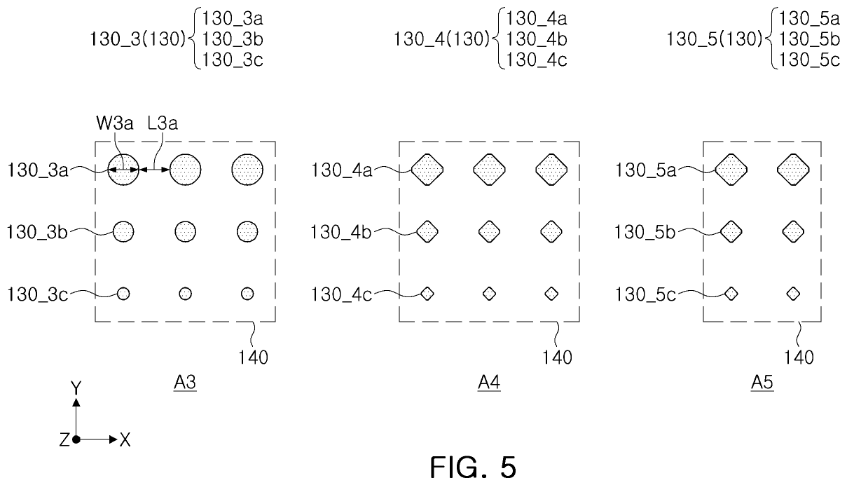

FIG. 4 is a partially enlarged view of the semiconductor package illustrated in FIG. 1. FIG. 5 is a partially enlarged view of the semiconductor package illustrated in FIG. 1. FIG. 4 may correspond to regions A1 and A2 illustrated in FIG. 1. FIG. 5 may correspond to regions A3, A4, and A5 illustrated in FIG. 1.

Referring further to FIGS. 4 and 5, the lower chip structure 120, the conductive posts 130, and the encapsulant 140 may be included in a connection structure CS. The connection structure CS may be disposed between the lower redistribution structure 110 and the upper redistribution structure 150, and may electrically connect the lower redistribution structure 110 and the upper redistribution structure 150 to each other.

In plan view, the connection structure CS may include a plurality of regions A1, A2, A3, A4, and A5 in which the conductive posts 130 are disposed. The plurality of regions A1, A2, A3, A4, and A5 may be arranged in an X-direction, and may be spaced apart from the lower chip structure 120 in a Y-direction. The plurality of regions A1, A2, A3, A4, and A5 may include a first region A1, a second region A2, a third region A3, a fourth region A4, and a fifth region A5. The plurality of regions A1, A2, A3, A4, and A5 illustrated in FIG. 1 are illustrative for ease of description, and are not limited thereto. In example embodiments, the connection structure CS may include a larger number of regions, and some regions may be arranged in the Y-direction.

First conductive posts 130_1 may be disposed in the first region A1. The first conductive posts 130_1 may include first conductive posts 130_1a, first conductive posts 130_1b, and first conductive posts 130_1c arranged in the X-direction. Second conductive posts 130_2 may be disposed in the second region A2. The second conductive posts 130_2 may include second conductive posts 130_2a, second conductive posts 130_2b, and second conductive posts 130_2c arranged in the X-direction. Third conductive posts 130_3 may be disposed in the third region A3. The third conductive posts 130_3 may include third conductive posts 130_3a, third conductive posts 130_3b, and third conductive posts 130_3c arranged in the X-direction. Fourth conductive posts 130_4 may be disposed in the fourth region A4. The fourth conductive posts 130_4 may include fourth conductive posts 130_4a, fourth conductive posts 130_4b, and fourth conductive posts 130_4c arranged in the X-direction. Fifth conductive posts 130_5 may be disposed in the fifth region A5. The fifth conductive posts 130_5 may include fifth conductive posts 130_5a, fifth conductive posts 130_5b, and fifth conductive posts 130_5c arranged in the X-direction.

In an example embodiment, pattern densities of the conductive posts 130, disposed in a plurality of regions A1, A2, A3, A4, and A5, may be different from each other. For example, as a distance from a center of the lower chip structure 120 increases (or a distance from a side surface or edge of the lower redistribution structure 110 decreases), the pattern densities of the conductive posts 130 may decrease. Here, in plan view, the pattern densities of the conductive posts 130 may refer to ratios per unit area of the conductive posts 130 with respect to the encapsulant 140. For example, among the first to fifth conductive posts 130_1, 130_2, 130_3, 130_4, and 130_5, the first conductive posts 130_1 may have a highest ratio per unit area with respect to the encapsulant 140, and the fifth conductive posts 130_5 may have a lowest ratio per unit area with respect to the encapsulant 140.

Cross-sectional areas of the conductive posts 130 may decrease as the distance from the center of the lower chip structure 120 increases. Here, the cross-sectional areas of the conductive posts 130 may refer to areas of the conductive posts 130 in plan view. For example, among the first to fifth conductive posts 130_1, 130_2, 130_3, 130_4, and 130_5, the first conductive posts 130_1 may have a largest cross-sectional area, and the fifth conductive posts 130_5 may have a smallest cross-sectional area. In an example embodiment, maximum horizontal widths of the first to fifth conductive posts 130_1, 130_2, 130_3, 130_4, and 130_5 may be equal to each other. However, some conductive posts, among the first to fifth conductive posts 130_1, 130_2, 130_3, 130_4, and 130_5, may have different shapes. For example, the first to fourth conductive posts 130_1, 130_2, 130_3, and 130_4 may have a rectangular shape, an octagonal shape, a circular shape, and an octagonal shape, respectively. The fifth conductive posts 130_5 may have an octagonal shape or a rectangular shape. FIGS. 4 and 5 illustrate that the conductive posts 130 have the same shape in the same regions A1, A2, A3, A4, and A5, but the present inventive concept is not limited thereto. For example, the first conductive posts 130_1 may have different shapes. For example, the first conductive posts 130_1a may have a rectangular shape, and the first conductive posts 130_1b and 130_1c may respectively have an octagonal shape and a circular shape.

A maximum horizontal width W1a of the first conductive post 130_1a may be equal to a maximum horizontal width W2a of the second conductive post 130_2a and a maximum horizontal width W3a of the third conductive post 130_3a. A distance L1a between the first conductive posts 130_1a may be equal to a distance L2a between the second conductive posts 130_2a and a distance L3a between the third conductive posts 130_3a.

In an example embodiment, maximum horizontal widths of the conductive posts 130, disposed in the same regions A1, A2, A3, A4, and A5, may be different from each other. For example, a maximum horizontal width of each of the first conductive posts 130_1 may decrease as the distance from the center of the lower chip structure 120 increases. A maximum horizontal width W1a of each of the first conductive posts 130_1a may be greater than a maximum horizontal width W1b of each of the first conductive posts 130_1b, and the maximum horizontal width W1b of each of the first conductive posts 130_1b may be greater than a maximum horizontal width W1c of each of the first conductive posts 130_1c.

The upper redistribution structure 150 may be disposed on the chip structure 120 and the encapsulant 140, and may include an upper insulating layer 151, an upper redistribution layer 152, and an upper redistribution via 153.

The upper insulating layer 151 may include an insulating resin. The insulating resin may include a thermosetting resin such as an epoxy resin, a thermoplastic resin such as polyimide, or a resin, for example, a prepreg, an ABF, FR-4, BT, or PID, in which the thermosetting resin or the thermoplastic resin is impregnated with an inorganic filler. The upper insulating layer 151 may include a plurality of second insulating layers 151 stacked in a vertical direction (Z-axis direction). Depending on a process thereof, the plurality of second insulating layers 151 may have unclear boundaries therebetween.

The upper redistribution layer 152 may be disposed on or in the upper insulating layer 151, and may redistribute the conductive posts 130. The upper redistribution layer 152 may include, for example, a metal material including copper (Cu), aluminum (Al), silver (Ag), tin (Sn), gold (Au), nickel (Ni), lead (Pb), titanium (Ti), or alloys thereof.

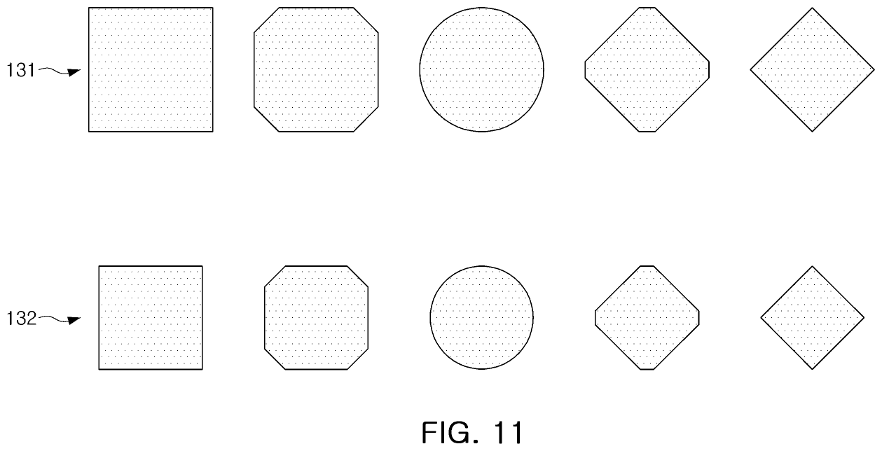

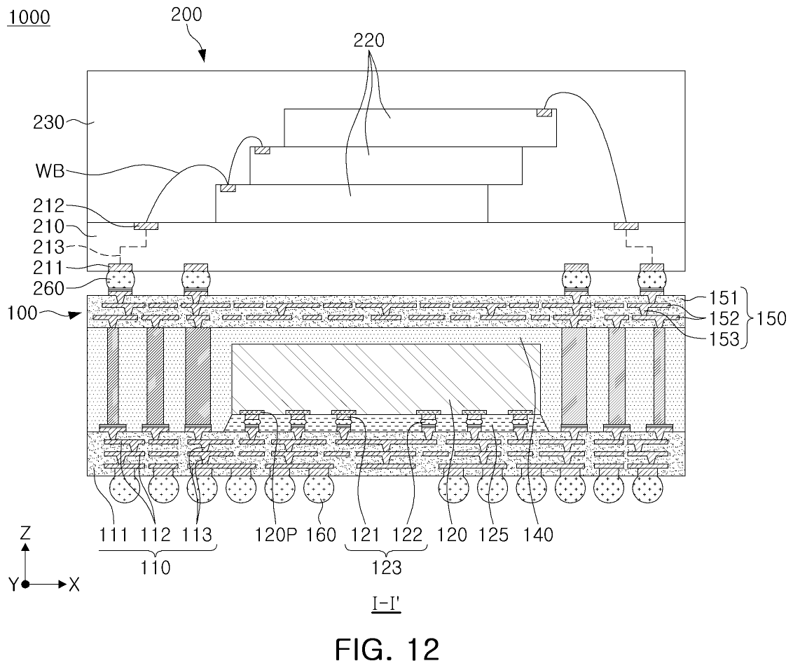

The number of redistribution layers, included in the upper redistribution layer 152, may be greater than or less than the number of those illustrated in the drawings. For example, the upper redistribution layer 152 may include a second pad portion P2 disposed on an upper surface of the upper redistribution structure 150. The second pad portion P2 may be physically and electrically connected to an external device (see FIG. 12). For example, a second barrier layer 155 may be disposed on a surface of the second pad portion P2. The second barrier layer 155 may include an oxidation-resistant material, for example, nickel (Ni), gold (Au), or alloys thereof. For example, the second barrier layer 155 may include a lower layer 155a including nickel (Ni) and an upper layer 155b including gold (Au).

The upper redistribution via 153 may pass through the upper insulating layer 151, and may be electrically connected to the upper redistribution layer 152. For example, the upper redistribution via 153 may interconnect the second redistribution layers 152 having different levels. The upper redistribution via 153 may be a filled via in which a metal material is filled in a via hole or a conformal via in which a metal material extends along an inner wall of a via hole.

The bump structure 160 may be disposed on a second surface of the lower redistribution structure 110. The bump structure 160 may be electrically connected to the chip structure 120 and the conductive post 130 through the lower redistribution layer 112. The semiconductor package 100 may be connected to an external device, such as a module substrate, a system board, or the like, through the bump structure 160. For example, the bump structures 160 may have a combination of a pillar (or underbump metal) and a ball. The pillar may include copper (Cu) or an alloy of copper (Cu), and the ball may include a low melting point metal, for example, an alloy (Sn—Ag—Cu) including tin (Sn) or tin (Sn). In some example embodiments, the bump structures 160 may include only the pillar or the ball. In some example embodiments, a resist layer (not illustrated), protecting the bump structures 160 from external physical and chemical damage, may be formed on the second surface.

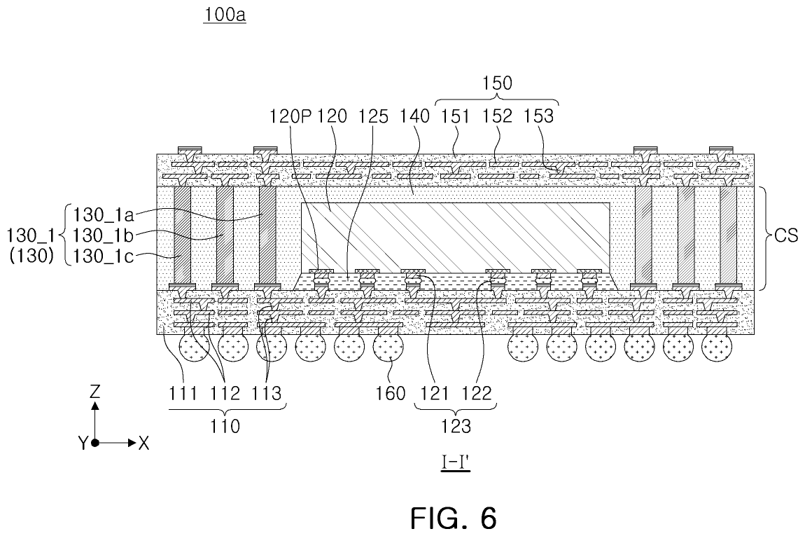

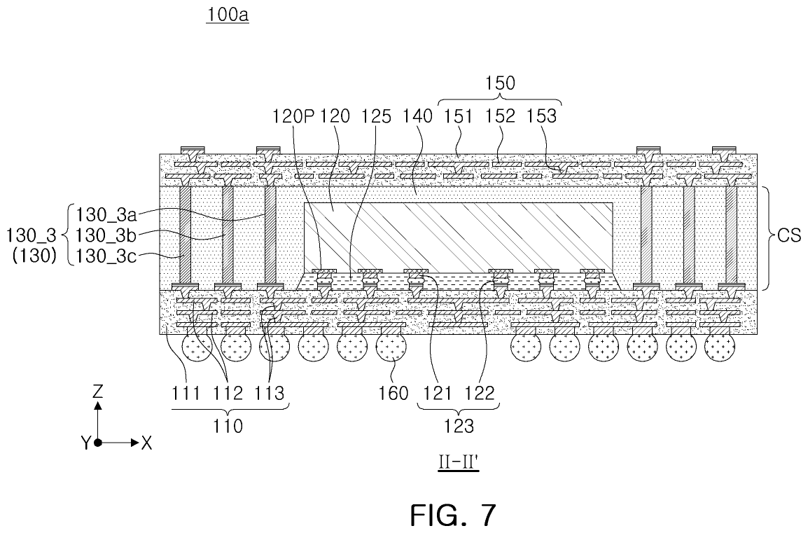

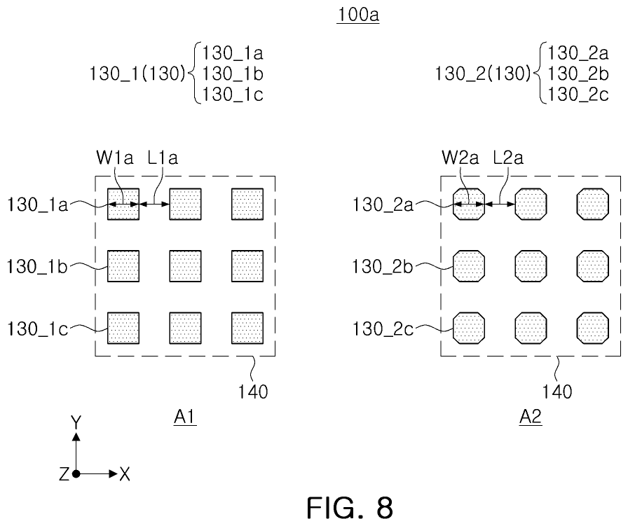

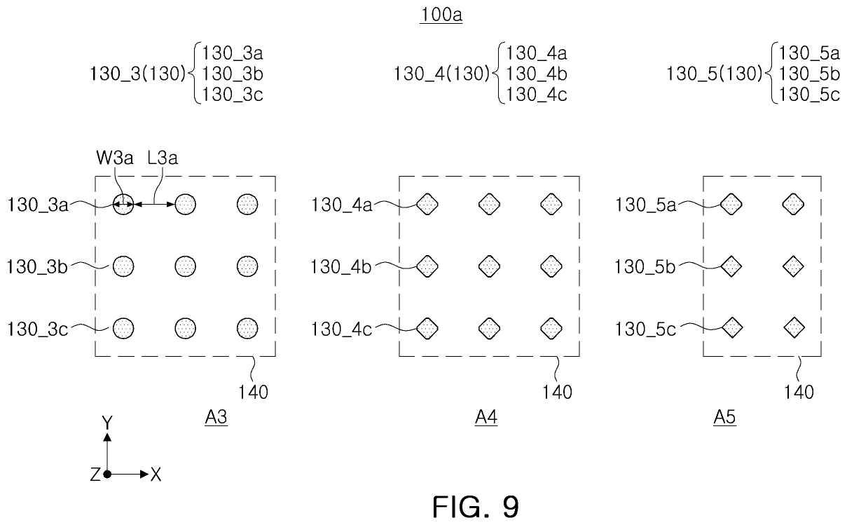

FIGS. 6 and 7 are vertical cross-sectional views of a semiconductor package according to an example embodiment. FIGS. 8 and 9 are plan views of a semiconductor package according to an example embodiment.

Referring to FIGS. 6 to 9, the semiconductor package 100a may include conductive posts 130 disposed around a lower chip structure 120. In an example embodiment, in each of the regions A1, A2, A3, A4, and A5, the conductive posts 130 may have the same horizontal width. For example, in each of the regions A1, A2, A3, A4, and A5, horizontal widths of the conductive posts 130 may be constant in a Y-direction. First conductive posts 130_1a, 130_1b, and 130_1c may have the same width, and third conductive posts 130_3a, 130_3b, and 130_3c may have the same width. A width of each of the first conductive posts 130_1 may be greater than a width of each of the third conductive posts 130_3.

Maximum horizontal widths of the conductive posts 130, disposed in different regions A1, A2, A3, A4, and A5, may be different from each other. For example, a maximum horizontal width W1a of each of the first conductive posts 130_1 and a maximum horizontal width W1b of each of the second conductive posts 130_2 may be greater than a maximum horizontal width W3a of each of the third conductive posts 130_3. The maximum horizontal width W1a of each of the first conductive posts 130_1 and the maximum horizontal width W1b of each of the second conductive posts 130_2 may also be greater than maximum horizontal widths of the fourth and fifth conductive posts 130_4 and 130_5. In an example embodiment, a distance L1a between the first conductive posts 130_1 and a distance L2a between the second conductive posts 130_2 may be less than a distance L3a between the third conductive posts 130_3.

FIG. 10 is a plan view of a semiconductor package according to an example embodiment.

Referring to FIG. 10, a semiconductor package 100b may include conductive posts 130 disposed around a lower chip structure 120. In an example embodiment, the conductive posts 130 may all have the same maximum horizontal width. For example, unlike that illustrated in FIG. 4, the first conductive posts 130_1 and the second conductive posts 130_2 may have the same horizontal width. Although not illustrated, horizontal widths of the first conductive posts 130_1 may be equal to horizontal widths of the third to fifth conductive posts 130_3, 130_4, and 130_5.

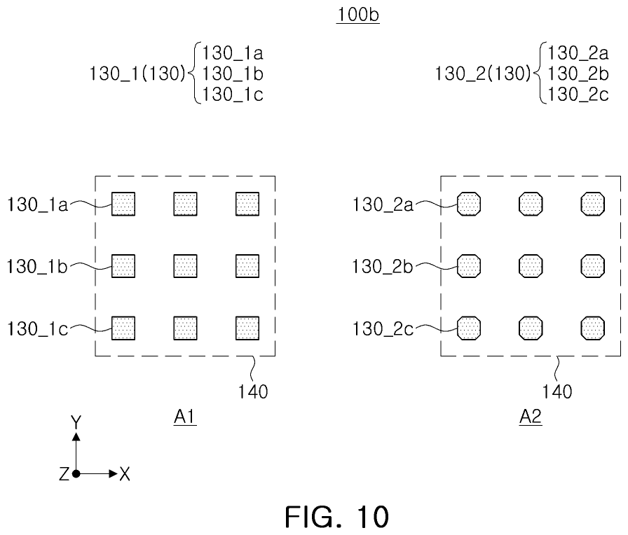

FIG. 11 illustrates conductive posts according to an example embodiment.

Referring to FIG. 11, the conductive posts 131 may have the same maximum horizontal width, but may have different shapes. Accordingly, cross-sectional areas of the conductive posts 131 may be changed by changing the shapes without changing the maximum horizontal widths. For example, the cross-sectional areas of the illustrated conductive posts 131 may increase leftwardly. A cross-sectional area of a leftmost conductive post 131 may be about twice a cross-sectional area of a rightmost conductive post 131. For example, the cross-sectional area of the leftmost conductive post 131 may be about 1.8 to 2.2 times the cross-sectional area of the rightmost conductive post 131.

Conductive posts 132 may also have the same maximum horizontal width, but may have different shapes. Maximum horizontal widths of the conductive posts 132 may be less than the maximum horizontal widths of corresponding conductive posts 131, respectively. Accordingly, comparing the conductive posts 132 and the conductive posts 131 to each other, cross-sectional areas of the conductive posts 132 may be changed by changing the maximum horizontal widths without changing the shapes. A cross-sectional area of a leftmost conductive post 131 may be about 2.45 times a cross-sectional area of a rightmost conductive post 132. For example, the cross-sectional area of the leftmost conductive post 131 may be about 2.25 to 2.65 times the cross-sectional area of the rightmost conductive post 132.

As described above, in example embodiments of the present disclosure, the cross-sectional areas of the conductive posts 130 may be changed by changing the maximum horizontal widths and/or shapes of the conductive posts 130, and the pattern densities of the conductive posts 130 may vary for each region.

FIG. 12 is a vertical cross-sectional view of a semiconductor package according to an example embodiment.

Referring to FIG. 12, a semiconductor package 1000 according to an example embodiment may include a first package 100 and a second package 200. The first package 100 in the semiconductor package 1000 is illustrated in the same manner as the semiconductor package 100 illustrated in FIG. 2, but the first package 100 may be replaced with the semiconductor packages 100a and 100b described with reference to FIGS. 6 to 10 or semiconductor packages having features similar to those of the semiconductor packages 100a and 100b. The first package 100 and the second package 200 may be referred to as a lower package and an upper package, respectively.

The second package 200 may include a redistribution substrate 210, an upper semiconductor chip 220, and an encapsulant 230. A lower surface and an upper surface of the redistribution substrate 210 may include a lower pad 211 and an upper pad 212 that may be electrically connected to the outside, respectively. In addition, the redistribution substrate 210 may include a redistribution circuit 213, electrically connecting the lower pad 211 and the upper pad 212 to each other.

The upper semiconductor chip 220 may be mounted on the redistribution substrate 210 in a wire bonding manner or a flip-chip bonding manner. For example, a plurality of upper semiconductor chips 220 may be stacked on the redistribution substrate 210 in a vertical direction, and may be electrically connected to the upper pad 212 of the redistribution substrate 210 by a bonding wire WB. For example, the upper semiconductor chip 220 may include a memory chip, and the lower chip structure 120 may include an AP chip. The plurality of upper semiconductor chips 220 may be referred to as an upper chip structure.

The encapsulant 230 may include a material, the same as or similar to that of the encapsulant 140 of the first package 100. The second package 200 may be physically and electrically connected to the first package 100 by a conductive bump 260. The conductive bump 260 may be electrically connected to the redistribution circuit 213 in the redistribution substrate 210 through the lower pad 211 of the redistribution substrate 210. The metal bump 260 may include a low melting point metal, for example, tin (Sn) or an alloy including tin (Sn).

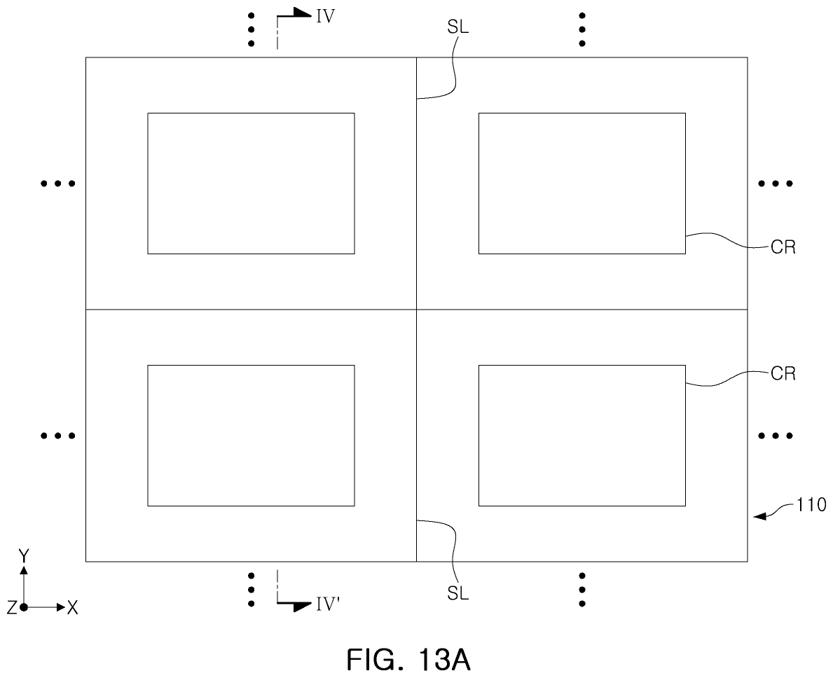

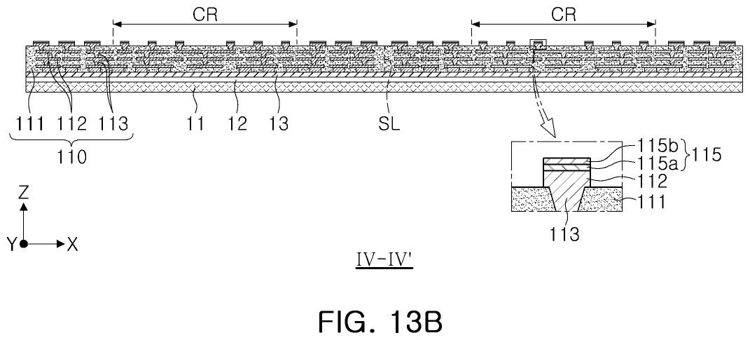

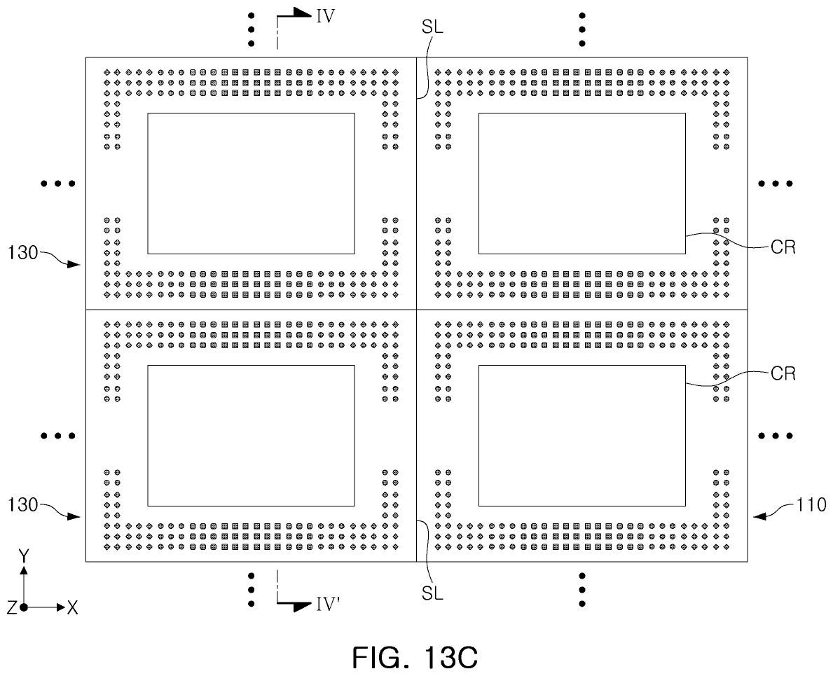

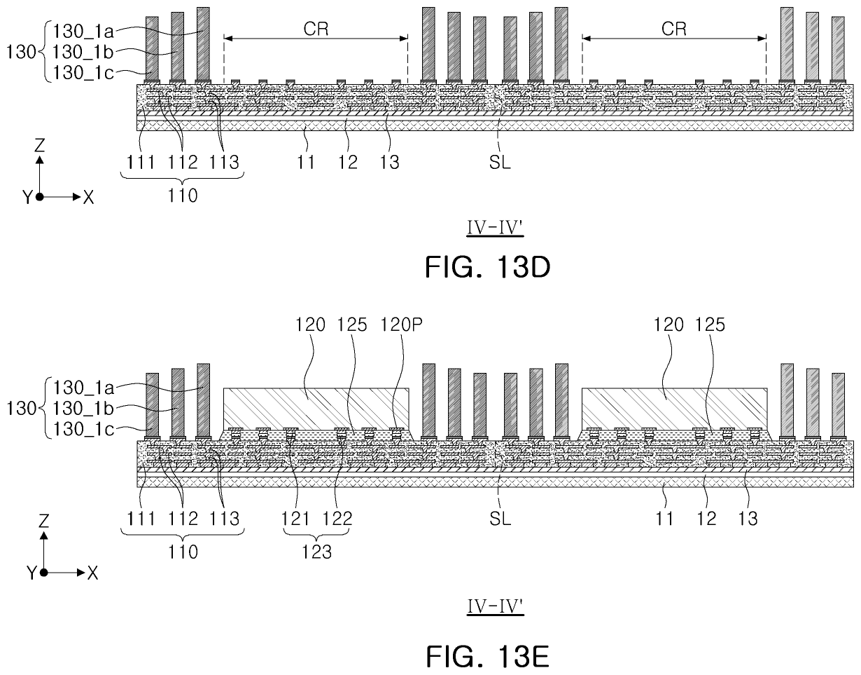

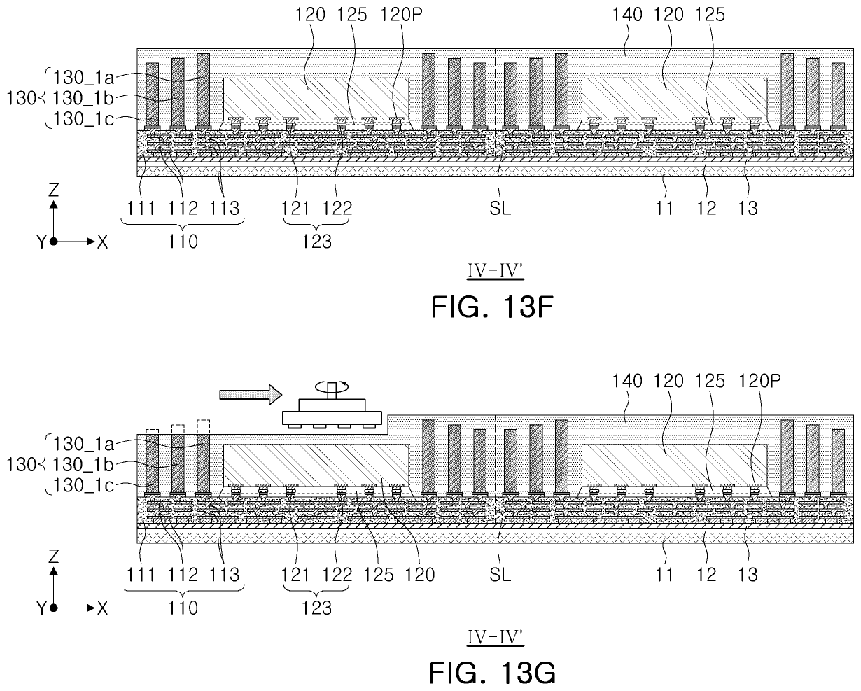

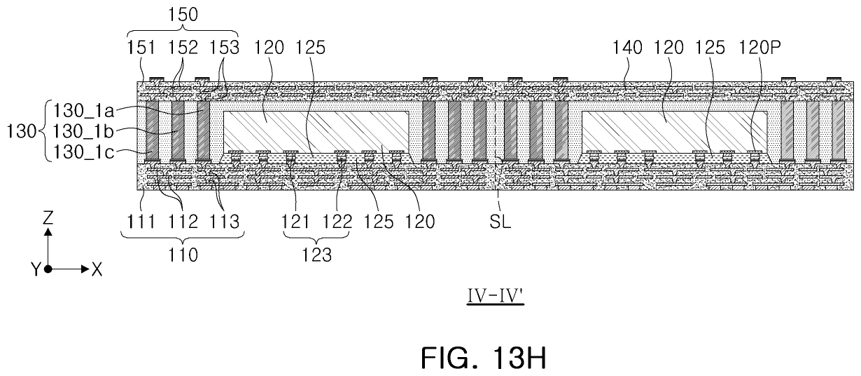

FIGS. 13A to 13H are plan views and vertical cross-sectional views of a method of manufacturing a semiconductor package according to an example embodiment. FIGS. 13B and 13D are vertical cross-sectional views taken along line IV-IV′ illustrated in FIGS. 13A and 13C, respectively.

Referring to FIGS. 13A and 13B, a lower redistribution structure 110 may be formed on a carrier. The carrier may include a lower layer 11, an intermediate layer 12, and an upper layer 13. The lower layer 11, the intermediate layer 12, and the upper layer 13 may include materials different from each other. For example, the lower layer 11 may be a copper clad laminate (CCL), the intermediate layer 12 may be a polymer layer including a curable resin, and the upper layer 13 may be a metal layer including nickel (Ni), titanium (Ti), or the like.

The lower redistribution structure 110 may include a lower insulating layer 111, a lower redistribution layer 112, and a lower redistribution via 113. The lower insulating layer 111 may be formed by sequentially coating and curing a photosensitive material, for example, a PID. The lower redistribution layer 112 and the lower redistribution via 113 may be formed by performing exposure and development processes to form a via hole passing through the lower insulating layer 111, and patterning a metal material on the lower insulating layer 111 using a plating process. The above-described process may be repeatedly performed to form a lower redistribution structure 110 including a plurality of first redistribution layers 112. A lower barrier layer 115 may be formed on an uppermost lower redistribution layer 112 disposed on an upper surface of the lower redistribution structure 110. The lower barrier layer 115 may be formed by sequentially plating nickel (Ni) and gold (Au). A bump structure 160 (pillar portion) may be formed below a lowermost redistribution layer 112, but the present inventive concept is not limited thereto. In some example embodiments, the bump structure 160 (pillar portion) may be formed after the carrier is entirely removed.

As illustrated in FIG. 13A, the lower redistribution structure 110 may include a plurality of chip regions CR. The chip regions CR may refer to a region on which the lower chip structure 120 illustrated in FIGS. 1 to 3 is mounted. The plurality of chip regions CR may be partitioned by scribe lanes SL. A region partitioned by the scribe lanes SL may correspond to each semiconductor package 100.

Referring to FIGS. 13C and 13D, conductive posts 130 may be formed on the uppermost lower redistribution layer 112. The conductive posts 130 may be formed by performing the plating process. The conductive posts 130 may include a metal material such as copper (Cu). In some example embodiments, a metal seed layer (not illustrated) including titanium (Ti), copper (Cu), or the like may be formed on lower surfaces of the conductive posts 130.

In an example embodiment, the conductive posts 130 may be formed to have different heights. For example, the conductive posts 130 may have a relatively low pattern density at a distance close to a center of the chip region CR, such that relatively high conductive posts 130 may be formed using the plating process. The conductive posts 130 may have a relatively high pattern density at a distance far from the center of the chip region CR, for example, at a distance close to the scribe lane SL, such that relatively low conductive posts 130 may be formed using the plating process. For example, the conductive posts 130 may include a first conductive post 130_1a, a second conductive post 130_1b, and a third conductive post 130_1c. The first conductive post 130_1a may be relatively close to the chip region CR, such that the first conductive post 130_1b may be formed to be higher than the second conductive post 130_1b and the third conductive post 130_1c.

Referring to FIG. 13E, the lower chip structure 120 may be disposed on the lower redistribution structure 110. The lower chip structure 120 may be mounted in a flip-chip manner. For example, the lower chip structure 120 may be connected to the lower redistribution layer 112 through a connection bump 123 formed on a connection pad 120P.

An underfill layer 125 may be formed between the lower chip structure 120 and the lower redistribution structure 110. The underfill layer 125 may be formed using a CUF process, but the present inventive concept is not limited thereto. In some example embodiments, the underfill layer 125 may be formed integrally with an encapsulant 140 to be described below using an MUF process.

Referring to FIG. 13F, the encapsulant 140 may be formed to encapsulate at least a portion of each of the lower chip structure 120 and the conductive post 130. The encapsulant 140 may be formed by, for example, coating and curing an EMC.

Referring to FIG. 13G, a planarization process may be applied to an upper portion of the encapsulant 140. The planarization process may include a grinding process, a chemical mechanical polishing (CMP) process, or the like. A portion of the conductive posts 130, a portion of the encapsulant 140, may be removed using the planarization process, and upper surfaces of the conductive posts 130 may be exposed. The conductive posts 130 may be coplanar with an upper surface of the encapsulant 140. A relatively high first conductive post 130_1a may be significantly etched using the planarization process.

Referring to FIG. 13H, an upper redistribution structure 150 may be formed on the conductive post 130 and the encapsulant 140. The upper redistribution structure 150 may be formed using a process, similar to that of the lower redistribution structure 110. Thereafter, the lower layer 11 may be separated, and the intermediate layer 12 and the upper layer 13 may be removed to expose a lower surface of the lower redistribution structure 110. Subsequently, the semiconductor package illustrated in FIG. 2 may be completed by attaching a solder ball to the bump structure 160 and performing a sawing process (not illustrated).

According to example embodiments of the present inventive concept, as described with reference to FIGS. 1 to 11, a maximum horizontal width of each of the conductive posts 130 may be changed to change a cross-sectional area of each of the conductive posts 130. In addition, the cross-sectional area of each of the conductive posts 130 may be changed by changing a shape of each of the conductive posts 130 without reducing a distance between the conductive posts 130. Accordingly, an increase in cross-sectional areas of relatively high conductive posts 130 may reduce heights of the conductive posts 130 even when the conductive posts 130, formed using plating, have the same volume. Accordingly, a variation in heights of the conductive posts 130 may be reduced. An amount of the conductive posts or the encapsulant 140, removed in the planarization process, may be reduced. Accordingly, costs required for a manufacturing process may be reduced. In addition, an electrical short circuit may be prevented from occurring between upper redistribution layers 152 of the upper redistribution structure 150 due to debris of the conductive posts 130, thereby reducing defects in the semiconductor package 100.

According to example embodiments of the present inventive concept, conductive posts may have a low pattern density in a region far from a center of a lower chip structure, thereby reducing a variation in heights of the conductive posts formed using a plating process. Accordingly, costs required for a semiconductor manufacturing process may be reduced, and defects in a semiconductor package may be prevented from occurring due to debris of the conductive posts removed in a planarization process.

While example embodiments have been shown and described above, it will be apparent to those skilled in the art that modifications and variations could be made without departing from the scope of the present inventive concept as defined by the appended claims.

What is claimed is:

1. A semiconductor package comprising:
a lower redistribution structure including a lower redistribution layer; and
a connection structure disposed on the lower redistribution structure,
wherein the connection structure includes a lower chip structure electrically connected to the lower redistribution layer, conductive posts disposed around the lower chip structure, and an encapsulant covering the lower chip structure and the conductive posts,
in a plan view, the connection structure includes a plurality of regions arranged in a first horizontal direction,
the plurality of regions are spaced apart from the lower chip structure in a second horizontal direction, intersecting the first horizontal direction,
the plurality of regions include a first region and a second region, farther from a center of the lower chip structure than the first region, and
the conductive posts in the second region have a shape, different from that of the conductive posts in the first region.

2. The semiconductor package of claim 1, wherein
the conductive posts include first conductive posts disposed in the first region, and second conductive posts disposed in the second region, and
a cross-sectional area of one of the first conductive posts is greater than a cross-sectional area of one of the second conductive posts.

3. The semiconductor package of claim 2, wherein a cross-sectional area of a first conductive post relatively close to the lower chip structure, among the first conductive posts, is greater than a cross-sectional area of a first conductive post relatively far from the lower chip structure, among the first conductive posts.

4. The semiconductor package of claim 2, wherein a maximum horizontal width of the one of the first conductive posts is equal to a maximum horizontal width of the one of the second conductive posts.

5. The semiconductor package of claim 2, wherein a maximum horizontal width of the one of the first conductive posts is greater than a maximum horizontal width of the one of the second conductive posts.

6. The semiconductor package of claim 2, wherein a distance between the first conductive posts is less than a distance between the second conductive posts.

7. The semiconductor package of claim 1, wherein
a maximum horizontal width of one of the conductive posts in the first region is equal to or greater than a maximum horizontal width of one of the conductive posts in the second region, and
the conductive posts in the first region have a rectangular shape, and the conductive posts in the second region have a circular shape.

8. The semiconductor package of claim 1, wherein a pattern density of the conductive posts in a region far from the lower chip structure, among the plurality of regions, is lower than a pattern density of the conductive posts in a region close to the lower chip structure, among the plurality of regions.

9. The semiconductor package of claim 1, wherein the conductive posts are arranged to have a predetermined pitch.

10. The semiconductor package of claim 1, further comprising:
an upper redistribution structure disposed on the connection structure, the upper redistribution structure electrically connected to the conductive posts.

11. The semiconductor package of claim 10, further comprising:
an upper package disposed on the upper redistribution structure,
wherein the upper package includes an upper chip structure electrically connected to the upper redistribution structure.

12. The semiconductor package of claim 1, wherein in each of the plurality of regions, in the plan view, a ratio per unit area of each of the conductive posts to the encapsulant decreases as a distance from the lower chip structure increases.

13. A semiconductor package comprising:
a lower redistribution structure including a lower redistribution layer;
a lower chip structure disposed on the lower redistribution structure, the lower chip structure electrically connected to the lower redistribution layer;
conductive posts arranged on the lower redistribution structure in a first horizontal direction, the conductive posts spaced apart from the lower chip structure in a second horizontal direction, intersecting the first horizontal direction; and
an encapsulant covering the lower chip structure and the conductive posts,
wherein in a plan view, a pattern density of the conductive posts decreases as a distance from a center of the lower chip structure increases,
the conductive posts include a first conductive post and a second conductive post farther from the center of the lower chip structure than the first conductive post, and
a cross-sectional area of the first conductive post is greater than a cross-sectional area of the second conductive post, and the first conductive post has a shape, different from that of the second conductive post.

14. The semiconductor package of claim 13, wherein in the plan view, a ratio per unit area of the conductive posts to the encapsulant decreases as the distance from the center of the lower chip structure increases.

15. The semiconductor package of claim 13, wherein a maximum horizontal width of the first conductive post is greater than a maximum horizontal width of the second conductive post.

16. The semiconductor package of claim 13, wherein the second conductive post is spaced apart from the first conductive post in the first horizontal direction, and is close to an edge of the lower redistribution structure.

17. The semiconductor package of claim 16, wherein
the conductive posts include a third conductive post spaced apart from the first conductive post in the second horizontal direction, the third conductive post farther from the center of the lower chip structure than the first conductive post, and
the cross-sectional area of the first conductive post is greater than a cross-sectional area of the third conductive post.

18. The semiconductor package of claim 17, wherein the third conductive post has a shape, different from that of the first conductive post.

19. The semiconductor package of claim 16, wherein
the conductive posts include a fourth conductive post spaced apart from the first conductive post in the second horizontal direction, the fourth conductive post closer to the center of the lower chip structure than the first conductive post, and
the cross-sectional area of the first conductive post is less than a cross-sectional area of the fourth conductive post.

20. A semiconductor package comprising:
a lower redistribution structure including a lower redistribution layer;
a bump structure disposed below the lower redistribution structure, the bump structure electrically connected to the lower redistribution layer; and
a connection structure disposed on the lower redistribution structure,
wherein the connection structure includes a lower chip structure electrically connected to the lower redistribution layer, conductive posts disposed around the lower chip structure, and an encapsulant covering the lower chip structure and the conductive posts,
upper surfaces of the conductive posts are coplanar with the encapsulant, and
in a plan view, the connection structure includes a plurality of regions arranged in a first horizontal direction,
the plurality of regions are spaced apart from the lower chip structure in a second horizontal direction, intersecting the first horizontal direction,
the plurality of regions include a first region and a second region, farther from a center of the lower chip structure than the first region,
a pattern density of the conductive posts in the second region is lower than a pattern density of the conductive posts in the first region, and
the conductive posts in the second region have a circular shape, and the conductive posts in the first region have a rectangular shape.
